(19) United States
(12) Patent Application Publication
(10) Pub. No.: US 2015/0162896 A1
(43) Pub. Date: Jun. 11, 2015

(54) DIGITAL FILTER CIRCUIT

(71) Applicant: Hidenori Kayama, Tokyo (JP)

(72) Inventor: Hidenori Kayama, Tokyo (JP)

(73) Assignee: NEC CORPORATION, Tokyo (JP)

(21) Appl. No.: 14/117,547

(22) PCT Filed: Apr. 19, 2012
(86) PCT No.: PCT/JP2012/061152

§ 371 Date: Nov. 13, 2013

(30) Foreign Application Priority Data
May 17, 2011 (JP) 2011-110286

(51) Int. Cl. H03H 17/02

(52) U.S. Cl. CPC H03H 17/0283; H03H 2218/06

(57) ABSTRACT

A digital filter circuit that implements a filtering process for a plurality of channels having different sampling rates with a small circuit complexity includes a delay circuit divided into first to mth groups of delay devices, processing stage division means for selectively supplying first to (m−1)th input delayed signals and output signals of the second to mth taps to the first to (m−1)th groups of delay devices, tap coefficient supply means for supplying first to mth selected tap coefficients, a multiplying circuit for multiplying outputs of the first to mth taps and the first to mth selected tap coefficients, an adding circuit for adding up first to mth multiplication results, an accumulative addition part for accumulatively adding the first to mth multiplication results and addition results of the plurality of adders, and an output data format generation part for generating an output format of a filtering process result of each of processing stages from the plurality of accumulative addition results and outputs of the adding circuit.

### TECHNICAL FIELD

The present invention relates to a digital filter circuit, and more particularly to a multichannel filter circuit for performing a filtering process on multiple channels.

### BACKGROUND ART

In recent years, along with reduction in size and electric power consumption of devices, a digital signal processor configured with an FPGA (Field Programmable Gate Array) or an ASIC (Application Specific Integrated Circuit) has also been demanded to be reduced in size and electric power consumption. For example, the circuit complexity of digital filter circuits used in the telecommunication field becomes larger because the digital filter circuits have sharp or narrow-band filter characteristics or need to process a string of a plurality of input data. Thus, simplification of circuits, particularly simplification of filter circuits that process the string of the plurality of input data having different sampling rates, has been examined.

Heretofore, various digital filter circuits have been proposed. For example, a digital filter circuit described in Non-Patent Literature 1 can perform a filtering process on a string of a plurality of input data in common with use of one filter circuit. Patent Literature 1 proposes a method of reducing electric power consumption in a filter process for the string of the plurality of input data. Each string of a plurality of input data is hereinafter referred to as a channel.

As will be described in greater detail below with reference to FIG. 1, a related multichannel filter circuit includes a delay circuit, a multiplying circuit, and an adding circuit. It is generally assumed that a multichannel filter circuit has n channels and m tap coefficients where n is an integer not less than 2 and m is an integer not less than 2. In this case, the delay circuit includes (n×m) delay devices, and the multiplying circuit includes m multipliers. Each of the multipliers receives, as input values, a delay output derived at an interval of n delay devices and a tap coefficient. The adding circuit adds up the multiplying results of the respective multipliers.

Inputs of n channels having a sampling rate of Fs are supplied to the multichannel filter circuit in an n-time-division format, which has a sampling rate of (n×Fs). Therefore, the multichannel filter circuit produces filter processing results of the respective channels in a time-division manner at the timing having a rate of (n×Fs).

In this manner, the related multichannel filter circuit receives an input data in a time-division manner and processes each channel at the time-divided timing Therefore, the related multichannel filter circuit has a more efficient configuration as compared to a configuration in which n single-channel filter circuits are arranged in parallel because the number of the multipliers, which have a large circuit complexity in particular, can be reduced by a factor of (1/n).

Furthermore, there have been known various other prior art references relating to the present invention.

For example, with regard to the technology of sampling a plurality of system signals having different frequencies with a single A/D converter, Patent Literature 2 discloses a method of determining a sampling rate of the A/D converter so as to minimize the sampling rate of the A/D converter as much as possible and to adjust a clock for subsequent digital signal processing into an integral number of times a clock of each system.

Furthermore, Patent Literature 3 discloses a technical idea relating to a filter that processes a plurality of baseband signals having the same rate (e.g., I-channel signals, Q-channel signals) in a time-division fashion.

Moreover, Patent Literature 4 discloses a digital filter circuit in which a re-sampling circuit is provided on an upstream side of the digital filter in order to process input signals having different rates by switching only frequencies of a processing clock without changing the cutoff characteristics of the same filter circuit.

### PRIOR ART REFERENCES

### Patent Literature

Patent Literature 1: JP-A 09-205346
Patent Literature 2: JP-A 2009-117925
Patent Literature 3: JP-A 07-038381
Patent Literature 4: JP-A 08-162905

### Non-Patent Literature

Non-Patent Literature 1: Xilinx Inc., “Logicore IP FIR Compiler v5.0,” Product Specification DS534, Apr. 19, 2010.

### SUMMARY OF INVENTION

### Problems to be Solved by Invention

However, there is a problem that the configuration of the related multichannel filter circuit is limited to a multichannel process for the same sampling rate.

Patent Literature 2 merely discloses a method of determining the sampling rate of the A/D converter when a plurality of system signals having different frequencies are received by the single A/D converter so that subsequent digital signal processing can be conducted efficiently. Thus, Patent Literature 2 is not an invention relating to a filtering process.

Patent Literature 3 merely discloses the technical idea corresponding to the aforementioned conventional multichannel filter circuit.

Patent Literature 4 needs to use processing clocks for different frequencies and also needs to additionally use an external resampler.

An object of the present invention is to provide a digital filter circuit that can implement a filtering process for a plurality of channels having different sampling rates with a small circuit complexity.

### Means for Solving Problems

The present invention provides a digital filter circuit characterized by performing a filtering process on a string of a plurality of input data having different sampling rates with a common circuit.

Specifically, in order to solve the above problems and to achieve the above object, according to the present invention, a digital filter circuit with m tap coefficients for performing a multichannel filtering process for different sampling rates having a maximum total sampling rate of (n×Fs) where m≧2 and n≧2 includes a delay circuit including (n×m) delay devices, the delay circuit being divided into first to mth groups of delay devices having first to mth taps, each groups of delay devices including n delay devices, processing step division means for selectively supplying first to (m−1)th input delayed signals obtained by delaying an input signal to the delay circuit by predetermined sampling intervals and output signals of the second to mth taps to the first to (m−1)th groups of delay devices so that the (n×m) delay devices can be divided into k processing step regions based upon the sampling rate of (k×Fs) where k≦n, tap coefficient supply means for supplying first to mth tap coefficients selected for the first to mth taps, respectively, a multiplying circuit first to mth multipliers for multiplying outputs of the first to mth taps and the first to mth selected tap coefficients to produce first to mth multiplication results, respectively, an adding circuit including a plurality of adders for adding up the first to mth multiplication results, an accumulative addition part including a plurality of accumulative adders for accumulatively adding the first to mth multiplication results and addition results of the plurality of adders to produce a plurality of accumulative addition results, an output data format generation part for generating an output format of a filtering process result of each of processing steps from the plurality of accumulative addition results and outputs of the adding circuit; and an accumulative addition control part for outputting a start signal of addition and a clear signal of the plurality of accumulative addition results to the plurality of accumulative adders.

### Advantageous Effects of Invention

According to a digital filter circuit of the present invention, a multichannel filter process can be performed on different sampling rates having the maximum total sampling rate of (n×Fs) with minimum additive circuit as compared to a conventional multichannel filter circuit.

### BRIEF DESCRIPTION OF DRAWINGS

FIG. 1 is a block diagram showing an example configuration of a related multichannel filter circuit (digital filter circuit);

FIG. 2 is a block diagram showing an example configuration of a multichannel filter circuit (digital filter circuit) according to an exemplary embodiment of the present invention;

FIG. 3 is a diagram showing a time-division input format in the multichannel filter circuit (digital filter circuit) according to the exemplary embodiment of the present invention;

FIG. 4 is a table showing the relationship between a sampling rate of an input signal, the number of divisions of processing steps, and a product-sum operation performed in each processing step region of the multichannel filter circuit (digital filter circuit) according to the exemplary embodiment of the present invention; and

FIG. 5 is an example of output coefficients of a coefficient setting part in the multichannel filter circuit (digital filter circuit) according to the exemplary embodiment of the present invention.

### MODES FOR CARRYING OUT THE INVENTION

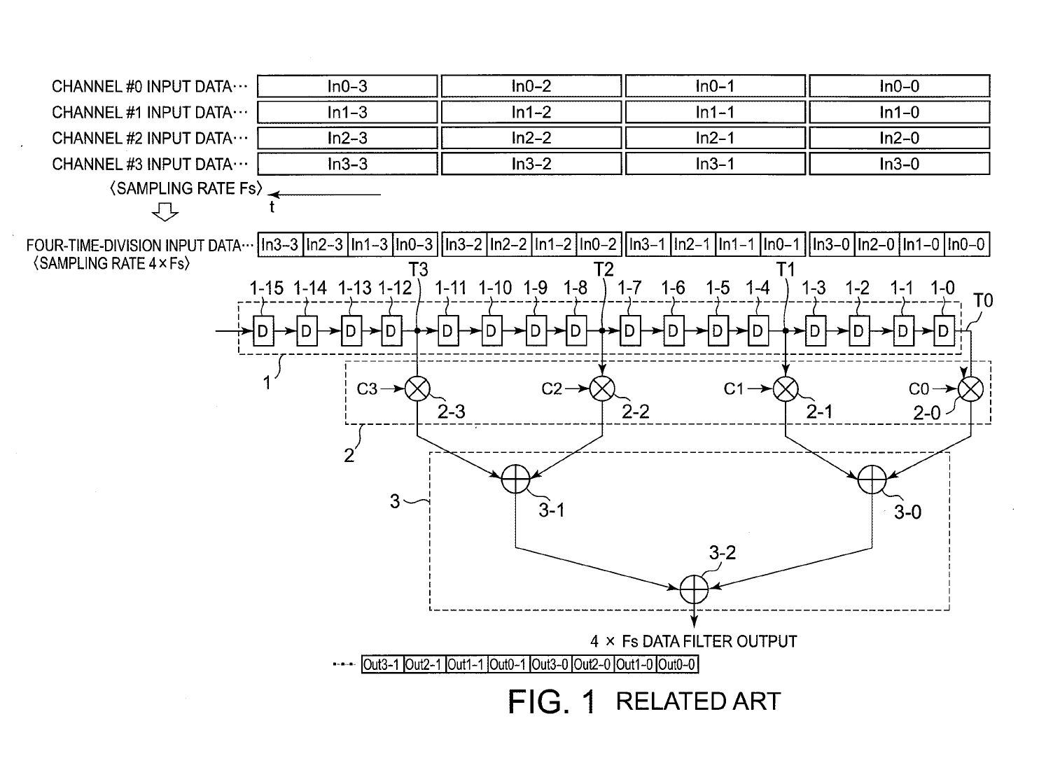

First referring to FIG. 1, a related multichannel filter circuit (digital filter circuit) will be described to facilitate the understanding of the present invention.

As shown in FIG. 1, the multichannel filter circuit (digital filter circuit) comprises a delay circuit 1, a multiplying circuit 2, and an adding circuit 3.

It is generally assumed that the multichannel filter circuit (digital filter circuit) has n channels and m tap coefficients where n is an integer not less than 2 and m is an integer not less than 2. In this case, the delay circuit 1 comprises (n×m) delay devices, and the multiplying circuit 2 comprises m multipliers. Each of the multipliers inputs a delay output derived at an interval of n delay devices and a tap coefficient. The adding circuit 3 adds up multiplication results of the respective multipliers.

FIG. 1 shows an example of the multichannel filter circuit where n, the number of channels is 4 and m, the number of taps is 4. Specifically, the multichannel filter circuit illustrated in FIG. 1 comprises a multichannel filter circuit having four channels and four tap coefficients.

In this case, the delay circuit 1 comprises first to sixteenth delay devices 1-0 to 1-15, the multiplying circuit 2 comprises first to fourth multipliers 2-0 to 2-3, and the adding circuit 3 comprises first to third adders 3-0 to 3-2.

As shown in FIG. 1, it is assumed that input data of channel #0 comprises In0-0, In0-1, In0-2, In0-3, . . . , input data of channel #1 comprises In1-0, In1-1, In1-2, In1-3, . . . , input data of channel #2 comprises In2-0, In2-1, In2-2, In2-3, . . . , and input data of channel #3 comprises In3-0, In3-1, In3-2, In3-3 . . . .

In such a case, inputs of four channels having a sampling rate Fs are supplied to the illustrated multichannel filter circuit with four channels and four tap coefficients in a four-time-division format having a sampling rate (4×Fs).

Specifically, the four-time-division input data comprises In0-0, In1-0, In2-0, In3-0, In0-1, In1-1, In2-1, In3-1, In0-2, In1-2, In2-2, In3-2, In0-3, In1-3, In2-3, In3-3 . . . .

Each of the first to sixteenth delay devices 1-0 to 1-15 supplies a unit delay T that is substantially equal to a reciprocal of the sampling rate of (4×Fs). That is, T=1/(4×Fs). For example, each of the first to fifteenth delay devices 1-0 to 1-15 is configured with a D flip-flop having a predetermined bit width, and all of the delay devices 1-0 to 1-15 constitute a 16-stage shift register. The unit delay T is also referred to as a sampling interval.

The delay circuit 1 has first to fourth taps T0, T1, T2, and T3. The first to sixteenth delay devices 1-0 to 1-15, which constitute the delay circuit 1, can be divided into first to fourth groups of delay devices. Specifically, the first to fourth delay devices 1-0 to 1-3 belong to a first group of delay devices, the fifth to eighth delay devices 1-4 to 1-7 belong to a second group of delay devices, the ninth to twelfth delay devices 1-8 to 1-11 belong to a third group of delay devices, and the thirteenth to sixteenth delay devices 1-12 to 1-15 belong to a fourth group of delay devices. The first group of delay devices (1-0 to 1-3) is disposed between the first tap T0 and the second tap T1, the second group of delay devices (1-4 to 1-7) is disposed between the second tap T1 and the third tap T2, the third group of delay devices (1-8 to 1-11) is disposed between the third tap T2 and the fourth tap T3, and the fourth group of delay devices (1-12 to 1-15) is disposed between the fourth tap T3 and an input terminal of the delay circuit 1.

The above-mentioned four-time-division input data is supplied to the input terminal of the delay circuit 1 in the aforementioned order and is delayed at the delay circuit 1. As a result, the input data are delayed by a delay time of 16 T (=4/Fs), which is equal to 16 times the unit delay Tat this delay circuit 1. Thus, as shown in FIG. 1, In0-0, In1-0, In2-0, In3-0, In0-1, In1-1, In2-1, In3-1, In0-2, In1-2, In2-2, In3-2, In0-3, In1-3, In2-3, and In3-3 are respectively outputted from output terminals of the first to sixteenth delay devices 1-0 to 1-15.

In the multiplying circuit 2, an output signal of the first tap T0 of the delay circuit 1 is supplied to one of input terminals of the first multiplier 2-0, and a first tap coefficient C0 is supplied to the other input terminal of the first multiplier 2-0. The first multiplier 2-0 multiplies the output signal of the first tap T0 and the first tap coefficient C0 together to produce a first multiplication result. Similarly, an output signal of the second tap T1 of the delay circuit 1 is supplied to one of input terminals of the second multiplier 2-1, and a second tap coefficient C1 is supplied to the other input terminal of the second multiplier 2-1. The second multiplier 2-1 multiplies the output signal of the second tap T1 and the second tap coefficient C1 together to produce a second multiplication result. An output signal of the third tap T2 of the delay circuit 1 is supplied to one of input terminals of the third multiplier 2-2, and a third tap coefficient C2 is supplied to the other input terminal of the third multiplier 2-2. The third multiplier 2-2 multiplies the output signal of the third tap T2 and the third tap coefficient C2 together to produce a third multiplication result. An output signal of the fourth tap T3 of the delay circuit 1 is supplied to one of input terminals of the fourth multiplier 2-3, and a fourth tap coefficient C3 is supplied to the other input terminal of the fourth multiplier 2-3. The fourth multiplier 2-3 multiplies the output signal of the fourth tap T3 and the fourth tap coefficient C3 together to produce a fourth multiplication result.

In the adding circuit 3, the first adder 3-0 adds the first multiplication result and the second multiplication result together to produce a first addition result. The second adder 3-1 adds the third multiplication result and the fourth multiplication result together to produce a second addition result. The third adder 3-2 adds the first addition result and the second addition result together to produce a third addition result. This third addition result is produced as a filter output ((4×Fs) data filter output) of the multichannel filter having four channels and four tap coefficients.

As described above, outputs of the delay devices (i.e., output signals of the first to fourth taps T0 to T3) are drawn at intervals of four delay devices in the first to sixteenth delay devices 1-0 to 1-15, which operate at a rate of (4×Fs). Those outputs of the delay devices (the output signals of the first to fourth taps T0 to T3) and the first to fourth tap coefficients C0 to C3 are respectively multiplied at the timing having a rate of (4×Fs) by the first to fourth multipliers 2-0 to 2-3. The outputs obtained by the multiplication at the same timing of the rate of (4×Fs) (the first to fourth multiplication results outputted from the first to fourth multipliers 2-0 to 2-3) are added up by the adding circuit 3, so that a filter output is produced.

Accordingly, at the process timing for the channel #0 of the rate of (4×Fs), outputs of the delay circuit 1 to the multiplying circuit 2 (i.e., the output signals of the first to fourth taps T0 to T3) are expressed by the following Formula 1.

{In0-0,In0-1,In0-2,In0-3} Formula 1

Those outputs are subjected to a product-sum operation with the first to fourth tap coefficients C0 to C3 at the subsequent multiplying circuit 2 and adding circuit 3. The product-sum output of the channel #0 is represented by the following Formula 2.

Out0-0=C0×In0-0+C1×In0-1+C2×In0-2+C3×In0-3 Formula 2

Similarly, the product-sum outputs of the channel #1, the channel #2, and the channel #3 are represented by the following Formulas 3, 4, and 5.

Out1-0=C0×In1-0+C1×In1-1+C2×In1-2+C3×In1-3 Formula 3

Out2-0=C0×In2-0+C1×In2-1+C2×In2-2+C3×In2-3 Formula 4

Out3-0=C0×In3-0+C1×In3-1+C2×In3-2+C3×In3-3 Formula 5

Thus, the filter processing results of the respective channels are produced in a time-division fashion at the timing of the rate of (4×Fs).

As described above, the related multichannel filter circuit (digital filter circuit) is supplied with input data in a time-division fashion and processes one channel at the time-divided timing. Therefore, the related multichannel filter circuit can be implemented with a more efficient configuration as compared to a configuration in which n single-channel filter circuits are arranged in parallel because the number of multipliers, which have a large circuit complexity in particular, can be reduced by a factor of (1/n).

However, as described above, there is a problem that the configuration of the related multichannel filter circuit (digital filter circuit) is limited to multichannel processing with the same sampling rate.

Next, a configuration of an exemplary embodiment according to the present invention will be described with reference to the drawings.

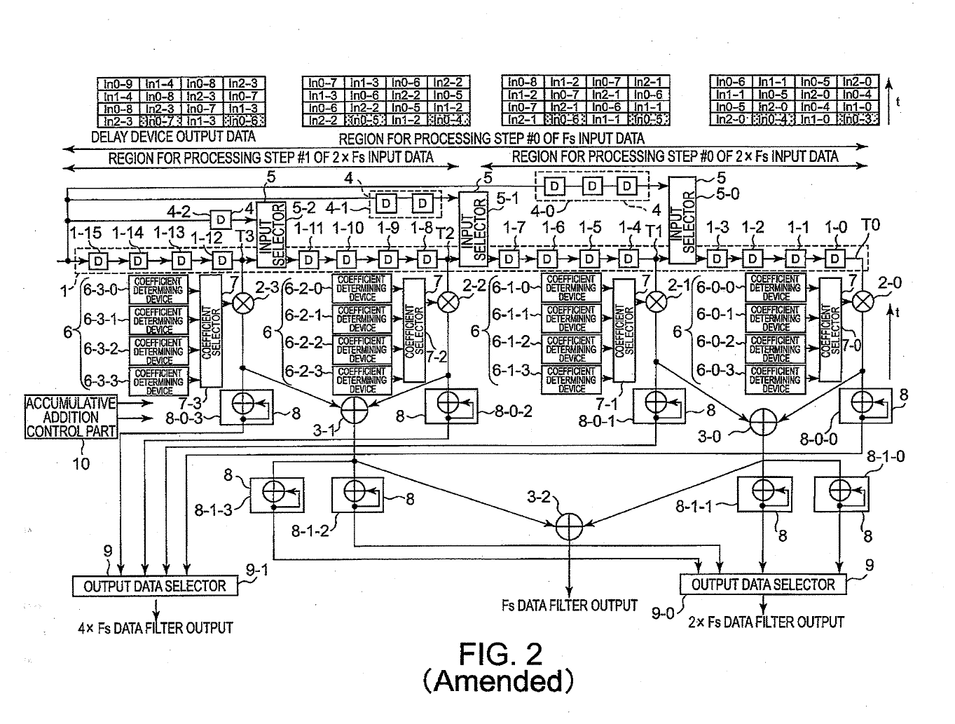

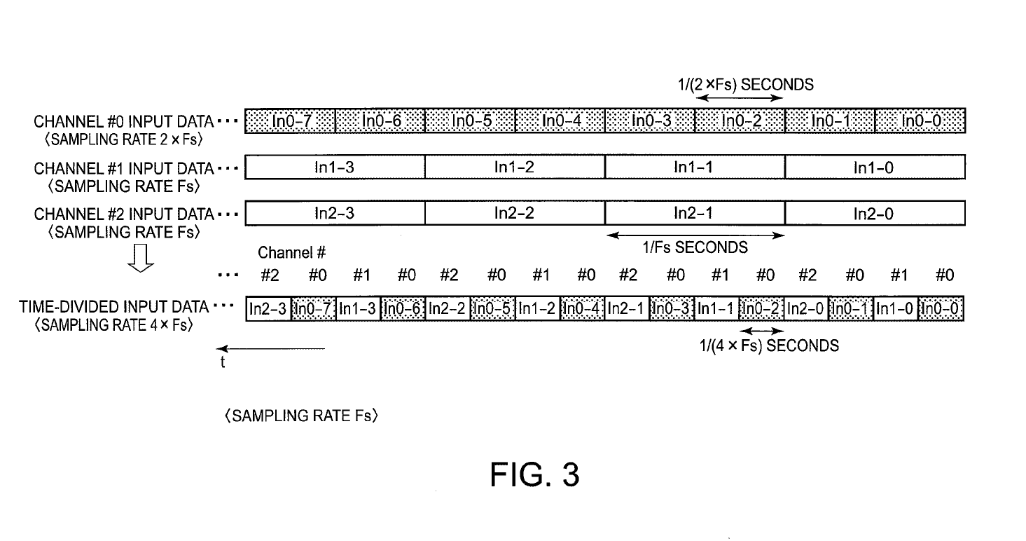

FIG. 2 is a block diagram showing a configuration example of a multichannel filter circuit (digital filter circuit) according to an exemplary embodiment of the present invention. FIG. 3 is a diagram showing an example of a time-division input format in the multichannel filter circuit (digital filter circuit) according to the exemplary embodiment of the present invention.

The illustrated multichannel filter circuit (digital filter circuit) according to the exemplary embodiment comprises a digital filter circuit with m tap coefficients for performing a multichannel filtering processing with different sampling rates where the maximum total sampling rate is (n×Fs). Here, n is an integer not less than 2 and m is an integer not less than 2.

As with the related multichannel filter circuit shown in FIG. 1, the illustrated multichannel filter circuit according to the exemplary embodiment comprises a delay circuit 1 including (n×m) delay devices, a multiplying circuit 2 including m multipliers, each of which inputs a delay output derived at an interval of n delay devices and an output of a coefficient selection part 7 (described later), and an adding circuit 3 operable to add up multiplication results of the respective multipliers.

The delay circuit 1 has first to mth taps T0 to T(m−1). The delay circuit 1 is divided into first to mth groups of delay devices, each of which include n delay devices. The multiplier 2 comprises first to mth multipliers 2-0 to 2-(m−1). The adding circuit 3 includes a plurality of adders as described later.

The multichannel filter circuit according to this exemplary embodiment further comprises a step-by-step data delay circuit 4, an input selection part 5, a coefficient determination part 6, a coefficient selection part 7, an accumulative addition part 8, an output data format generation part 9, and an accumulative addition control part 10.

The stage-by-stage data delay circuit 4 has a sampling rate of (k×Fs) where k≦n. The stage-by-stage data delay circuit 4 comprises first to (m−1)th processing stage data delay devices 4-0 to 4-(m−2) operable to output first to (m−1)th input delayed signals produced by delaying channels whose filtering process has been divided into k processing step regions by required sampling intervals corresponding to the processing stage regions.

The input selection part 5 is operable to divide the (n×m) delay devices into k processing stage regions based upon the sampling rate (k×Fs) of the channel being processed where k≦n and to supply the first to (m−1)th input delayed signals and outputs of the second to mth taps T1 to T(m−1) selectively to the first to (m−1)th groups of delay devices.

Specifically, a combination of the stage-by-stage data delay circuit 4 and the input selection part 5 serves as processing stage division means (4, 5) that can divide the (n×m) delay devices into k processing stage regions based upon the sampling rate (k×Fs) where k≦n by inputting the first to (m−1) input delayed signals, which have been produced by delaying the input signals to the delay circuit 1 by the required sampling intervals, and the output signals of the second to mth taps T1 to T(m−1) selectively to the first to (m−1)th groups of delay devices.

The coefficient determination part 6 determines tap coefficients for first to mth taps T0 to T(m−1) corresponding to the filtering processes of the respective processing stage regions based upon the multichannel sampling rate configuration. The coefficient determination part 6 comprises first to mth groups of coefficient determining devices, each of which comprises a plurality of coefficient determining devices (described later).

The coefficient selection part 7 selectively outputs groups of tap coefficients outputted from the first to mth groups of coefficient determining devices as first to mth selected tap coefficients to the first to mth multipliers 2-0 to 2-(m−1) with the maximum total sampling rate (n×Fs).

Specifically, a combination of the coefficient determination part 6 and the coefficient selection part 7 serves as tap coefficient supply means (6, 7) for supplying the first to mth selected tap coefficients that have been selected for the first to mth taps T0 to T(m−1).

In the multiplying circuit 2, the first to mth multipliers 2-0 to 2-(m−1) multiply outputs of the first to mth taps T0 to T(m−1) and the first to mth selected tap coefficients together, respectively, to produce the first to mth multiplication results, respectively.

The adding circuit 3 comprises a plurality of adders for adding up the first to mth multiplication results.

The accumulative addition part 8 accumulatively adds up k multiplication results or product-sum operation results of the respective processing stages. Specifically, the accumulative addition part 8 comprises a plurality of accumulative adders (described later) for accumulatively adding up the first to mth multiplication results and the addition results of the aforementioned adders to produce a plurality of accumulative addition results.

The output data format generation part 9 generates an output format of the filtering process results of the respective processing stages from the aforementioned accumulative addition results and the outputs of the adding circuit 3.

The accumulative addition control part 10 outputs a start signal for addition and a clear signal for the accumulative addition results to the accumulative adders.

As with the conventional multichannel filter circuit shown in FIG. 1, the multichannel filter circuit shown in FIG. 2 is an example where n, the maximum number of channels is equal to four and m, the number of taps is equal to four.

Therefore, the delay circuit 1 comprises first to sixteenth delay devices 1-0 to 1-15, the multiplying circuit 2 comprises first to fourth multipliers 2-0 to 2-3, and the adding circuit 3 comprises first to third adders 3-0 to 3-2.

The connection relationship and operation of the delay circuit 1, the multiplying circuit 2, and the adding circuit 3 are the same as described with reference to FIG. 1, and the explanation thereof is omitted herein for the sake of brevity.

The stage-by-stage data delay circuit 4 comprises first to third stage-by-stage data delay devices 4-0, 4-1, and 4-2. The input selection part 5 comprises first to third input selectors 5-0, 5-1, and 5-2.

The first stage-by-stage data delay device 4-0 comprises three stages of shift registers having three D flip-flops in cascade connection. The first stage-by-stage data delay device 4-0 delays input data to be supplied to an input terminal of the delay circuit 1 by 3 T (three sampling intervals) and supplies a delayed data as a first input delay signal to one of input terminals of the first input selector 5-0. The first input selector 5-0 has the other input terminal connected to the second tap T1 of the delay circuit 1. The first input selector 5-0 selects one of the data (first input delay signal) delayed by the first stage-by-stage data delay device 4-0 and the output signal of the second tap T1 and supplies a selected signal to the first group of delay devices (1-0 to 1-3).

The second stage-by-stage data delay device 4-1 includes two stages of shift registers having two D flip-flops in cascade connection. The second stage-by-stage data delay device 4-1 delays the input data to be supplied to the input terminal of the delay circuit 1 by 2 T (two sampling intervals) and supplies a delayed data as a second input delay signal to one of input terminals of the second input selector 5-1. The second input selector 5-1 has the other input terminal connected to the third tap T2 of the delay circuit 1. The second input selector 5-1 selects one of the data (second input delay signal) delayed by the second stage-by-stage data delay device 4-1 and the output signal of the third tap T2 and supplies a selected signal to the second group of delay devices (1-4 to 1-7).

The third stage-by-stage data delay device 4-2 comprises one D flip-flop. The third stage-by-stage data delay device 4-2 delays the input data to be supplied to the input terminal of the delay circuit 1 by 1 T (one sampling interval) and supplies a delayed data as a third input delay signal to one of input terminals of the third input selector 5-2. The third input selector 5-2 has the other input terminal connected to the fourth tap T3 of the delay circuit 1. The third input selector 5-2 selects one of the data (third input delay signal) delayed by the third stage-by-stage data delay device 4-2 and the output signal of the fourth tap T3 and supplies a selected signal to the third group of delay devices (1-8 to 1-11).

The coefficient determination part 6 comprises 16 coefficient determining devices. Specifically, the coefficient determination part 6 comprises first to sixteenth coefficient determining devices 6-0-0, 6-0-1, 6-0-2, 6-0-3, 6-1-0, 6-1-1, 6-1-2, 6-1-3, 6-2-0, 6-2-1, 6-2-2, 6-2-3, 6-3-0, 6-3-1, 6-3-1, 6-3-2, and 6-3-3. The first to sixteenth coefficient determining devices 6-0-0 to 6-3-3 are grouped into first to fourth groups of coefficient determining devices, each of which include four determining devices.

In other words, the first to fourth coefficient determining devices 6-0-0, 6-0-1, 6-0-2, and 6-0-3 belong to the first group of coefficient determining devices 6-0-X(0≦X≦3), the fifth to eighth coefficient determining devices 6-1-0, 6-1-1, 6-1-2, and 6-1-3 belong to the second group of coefficient determining devices 6-1-X the ninth to twelfth coefficient determining devices 6-2-0, 6-2-1, 6-2-2, and 6-2-3 belong to the third group of coefficient determining devices 6-2-X and the thirteenth to sixteenth coefficient determining devices 6-3-0, 6-3-1, 6-3-1, 6-3-2, and 6-3-3 belong to the fourth group of coefficient determining devices 6-3-X.

Specifically, the first group of coefficient determining devices (6-0-0 to 6-0-3) is for determining the tap coefficient for the first tap T0, the second group of coefficient determining devices (6-1-0 to 6-1-3) is for determining the tap coefficient for the second tap T1, the third group of coefficient determining devices (6-2-0 to 6-2-3) is for determining the tap coefficient for the third tap T2, and the fourth group of coefficient determining devices (6-3-0 to 6-3-3) is for determining the tap coefficient for the fourth tap T3.

The coefficient selection part 7 comprises first to fourth coefficient selectors 7-0, 7-1, 7-2, and 7-3. The first coefficient selector 7-0 selects one coefficient determining device from the first group of coefficient determining devices (6-0-0 to 6-0-3) and supplies a first selected tap coefficient to the first multiplier 2-0. The second coefficient selector 7-1 selects one coefficient determining device from the second group of coefficient determining devices (6-1-0 to 6-1-3) and supplies a second selected tap coefficient to the second multiplier 2-1. The third coefficient selector 7-2 selects one coefficient determining device from the third group of coefficient determining devices (6-2-0 to 6-2-3) and supplies a third selected tap coefficient to the third multiplier 2-2. The fourth coefficient selector 7-3 selects one coefficient determining device from the fourth group of coefficient determining devices (6-3-0 to 6-3-3) and supplies a fourth selected tap coefficient to the fourth multiplier 2-3.

The accumulative addition part 8 comprises first to eighth accumulative adders 8-0-0, 8-0-1, 8-0-2, 8-0-3, 8-1-0, 8-1-1, 8-1-2, and 8-1-3.

The first accumulative adder 8-0-0 accumulates the first multiplication result produced by the first multiplier 2-0 to produce a first accumulative addition result. The second accumulative adder 8-0-1 accumulates the second multiplication result produced by the second multiplier 2-1 to produce a second accumulative addition result. The third accumulative adder 8-0-2 accumulatively adds up the third multiplication result produced by the third multiplier 2-2 to produce a third accumulative addition result. The fourth accumulative adder 8-0-3 accumulatively adds up the fourth multiplication result produced by the fourth multiplier 2-3 to produce a fourth accumulative addition result.

The fifth accumulative adder 8-1-0 accumulatively adds up the first addition result produced by the first adder 3-0 as described later to produce a fifth accumulative addition result. The sixth accumulative adder 8-1-1 accumulatively adds up the first addition result produced by the first adder 3-0 as described later to produce a sixth accumulative addition result. The seventh accumulative adder 8-1-2 accumulatively adds up the second addition result produced by the second adder 3-1 as described later to produce a seventh accumulative addition result. The eighth accumulative adder 8-1-3 accumulatively adds up the second addition result produced by the second adder 3-1 to produce an eighth accumulative addition result.

The output data format generation part 9 comprises first and second output data selectors 9-0 and 9-1. The first output data selector 9-0 selectively produces the fifth to eighth accumulative addition results produced by the fifth to eighth accumulative adders 8-1-0 to 8-1-3. The second output data selector 9-1 selectively produces the first to fourth accumulative addition results produced by the first to fourth accumulative adders 8-0-0 to 8-0-3.

The input data of FIG. 2 are supplied to the delay circuit 1, which operates at the maximum total sampling rate of (4×Fs), with one channel having a sampling rate of (2×Fs) and two channels having a sampling rate of Fs as shown in FIG. 3 in the order of the channel #0, the channel #1, the channel #0, the channel #2, . . . with the maximum total sampling rate of (4×Fs).

More specifically, one channel (channel #0) of the input data having a sampling rate of (2×Fs) includes In0-0, In0-1, In0-2, In0-3, In0-4, In0-5, In0-6, In0-7, . . . . One of two channels (channel #1) of the input data having a sampling rate of Fs includes In1-0, In1-1, In1-2, In1-3, . . . . The other channel (channel #2) of the input data includes In2-0, In2-1, In2-2, In2-3 . . . .

In this case, the time-divided input data having the maximum total sampling rate of (4×Fs) includes In0-0, In1-0, In0-1, In2-0, In0-2, In1-1, In0-3, In2-1, In0-4, In1-2, In0-5, In2-2, In0-6, In1-3, In0-7, In2-3 . . . .

At that time, each channel of the input data is supplied to the processing stage region of the delay circuit 1 that performs k processing steps according to the sampling rate (k×Fs) of the channel where k≦4 after it has been delayed at the stage-by-stage data delay circuit 4 by a required sampling interval.

Specifically, the first to sixteenth delay devices 1-0 to 1-15 are used as a region for the processing stage #0 of the input data having a sampling rate of Fs. On the other hand, the first to eighth delay devices 1-0 to 1-7 are used as a region for the processing stage #0 of the input data having a sampling rate of (2×Fs), and the ninth to sixteenth delay devices 1-8 to 1-15 are used as a region for the processing stage #1 of the input data having a sampling rate of (2×Fs).

Division of the processing stages of the filtering process will be described along with an example of a filtering process having four tap coefficients.

When the input signals are defined as {In0, In1, In2, In3 . . . }, the first to fourth tap coefficients as {C0, C1, C2, C3}, and the output signals as {Out0, Out1, Out2, Out3 . . . }, then the output signals are given by the following formulas 6.

Out0=C0×In0+C1×In1+C2×In2+C3×In3

Out1=C0×In1+C1×In2+C2×In3+C3×In4

Out2=C0×In2+C1×In3+C2×In4+C3×In5

Out3=C0×In3+C1×In4+C2×In5+C3×In6: Formulas 6

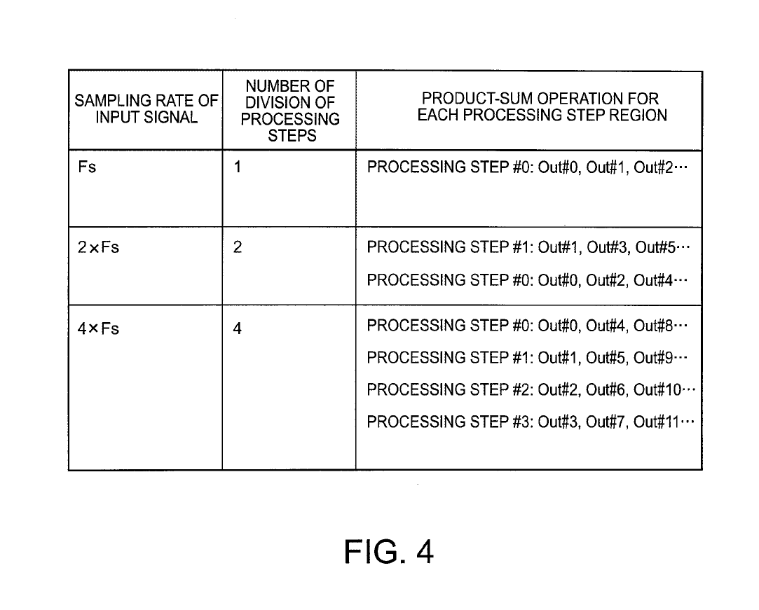

FIG. 4 is a table showing the relationship between the sampling rate (k×Fs) of the input signal according to the present exemplary embodiment, the number of divisions of the processing stages, and the product-sum operation performed in each of the processing stage regions.

An input signal having a sampling rate of (2×Fs) according to the present exemplary embodiment is subjected to a product-sum operation for the processing stage #0 (Out1, Out3, Out5, . . . ) and a product-sum operation for the processing stage #1 (Out0, Out2, Out4, . . . ) with use of the processing stage regions of a first half (1-0 to 1-7) and a second half (1-8 to 1-15) of the first to sixteenth delay devices 1-0 to 1-15, which interpose the second input selection part 5-1 therebetween.

If the output of the ninth delay device 1-8 in a first stage comprises input data having a sampling rate of (2×Fs) at the timing of operation of each of the delay devices 1-0 to 1-15, then the second input selector 5-1 selects the output of the second stage-by-stage data delay device 4-1 and outputs it to a second stage (1-0 to 1-7). If the output of the ninth delay device 1-8 in the first stage comprises input data having a sampling rate of Fs, then the second input selector 5-1 selects the output of the ninth delay device 1-8 in the region of the first stage for the processing stage #1 (i.e., the output of the third tap T2) and outputs it to the second stage.

The second stage-by-stage data delay device 4-1 outputs to the region for the processing stage #0 (1-0 to 1-7) the input data (second input delayed signal) delayed more than the region for processing stage #1 (1-8 to 1-15) of the input data having a sampling rate of (2×Fs) by two sampling intervals. Thus, product-sum operations can be performed for different processing stages at the same timing in both of the processing state regions.

Furthermore, a product-sum operation for the processing step #0 (Out0, Out1, Out2, . . . ) is performed on the input signal having a sampling rate of Fs with the region for the processing step #0, which extends across the whole of the first to fifteenth delay devices 1-0 to 1-15, in a manner in which channels are time-divided.

When one channel having a sampling rate of (4×Fs) is supplied, the first and third input selectors 5-0 and 5-2 divide the first to sixteenth delay devices 1-0 to 1-15 into four processing step regions along with the second input selector 5-1 and select input data for each of the processing stage regions. When one channel having a sampling rate of (4×Fs) is supplied, the first and third stage-by-stage data delay devices 4-0 and 4-2 delay data to be supplied to the first, third, and second input selection parts 5-0, 5-2, and 5-1 by three sampling intervals (3 T), one sampling interval (1 T), and two sampling intervals (2 T), respectively, along with the second stage-by-stage data delay device 4-1.

In this manner, the regions on the first to sixteenth delay devices 1-0 to 1-15 are divided into the number of processing stages that corresponds to the sampling rate of input signals. A product-sum operation is performed on each of the processing stages. Therefore, the number of tap coefficients should preferably be a common multiple of all possible values of k in view of the circuit configuration. Since the configuration of this exemplary embodiment assumes cases where k=1, 2, or 4, the number of tap coefficients should preferably be a multiple of 4.

In order to perform a product-sum operation on each of the processing stages corresponding to a plurality of inputted channels having different sampling rates as described above, the coefficient determination part 6 determines and produces tap coefficients based upon the rate configuration of multiple channels.

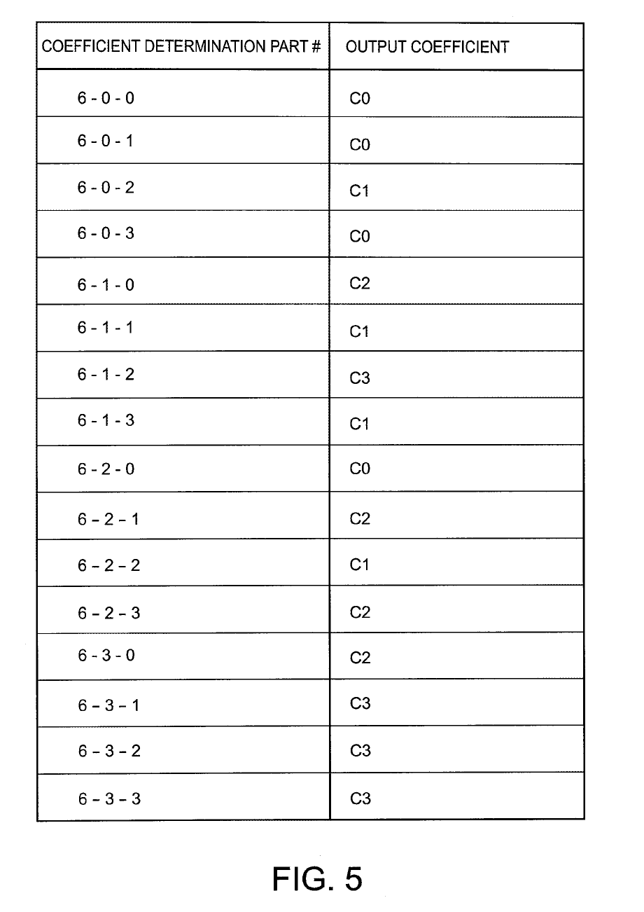

FIG. 5 shows output coefficients of the coefficient determination part 6 in the rate configuration of input data according to the present exemplary embodiment ((2×Fs) input data×1+Fs input data×2).

FIG. 5 shows an output coefficient table specialized in the aforementioned rate configuration. The coefficient determining devices 6-0-0 to 6-3-3 hold output coefficients corresponding to the number of rate configuration patterns of channels in which the maximum total sampling rate is (4×Fs) and selectively produce the output coefficients based upon the rate configuration of the channels.

The coefficient selection part 7 sequentially selects and produces coefficients to be produced by the coefficient determination part 6 at the same rate of (4×Fs) as the first to sixteenth delay devices 1-0 to 1-15 in the order of the coefficient determining devices 6-x-0, 6-x-1, 6-x-2, 6-x-3, 6-x-0, . . . .

In the adding circuit 3, the first adder 3-0 adds up the first multiplication result of the first multiplier 2-0 and the second multiplication result of the second multiplier 2-1 and produces a first addition result. The second adder 3-1 adds up the third multiplication result of the third multiplier 2-2 and the fourth multiplication result of the fourth multiplier 2-3 and produces a second addition result. The third adder 3-2 adds up the first addition result of the first adder 3-0 and the second addition result of the second adder 3-1 and produces a third addition result.

The fifth and seventh accumulative adders 8-1-0 and 8-1-2 perform an accumulative addition during a period in the four-time-division format that corresponds to the channel, at the processing timing of the channel on the first and second addition results of the first and second adders 3-0 and 3-1 for the channel having a sampling rate of (2×Fs).

The sixth and eighth accumulative adders 8-1-1 and 8-1-3 are accumulative adders for the second channel of data when two channels are supplied with a sampling rate of (2×Fs). The first to fourth accumulative adders 8-0-0 to 8-0-3 are accumulative adders for the multiplication result of each of the processing stages when one channel is supplied with a sampling rate of (4×Fs).

The accumulative addition control part 10 produces a start signal of addition and a clear signal of an accumulative addition result to each of the accumulative adders 8-0-0 to 8-1-3.

In the output data format generation part 9, the first output data selector 9-0 inputs accumulative addition results for the processing stage #0 and the processing stage #1 with respect to the channel having a sampling rate of (2×Fs) and generates and produces an output format. Specifically, the first output data selector 9-0 selectively produces the fifth to eighth accumulative addition results produced by the fifth to eighth accumulative adders 8-1-0, 8-1-1, 8-1-2, and 8-1-3.

The filtering results of the input data having a sampling rate of Fs are produced in a time-division manner from the third adder 3-2.

Furthermore, when a channel having a sampling rate of (4×Fs) is supplied, the second output data selector 9-1 receives accumulative addition results of the respective processing stages and generates and produces an output format. Specifically, the second output data selector 9-1 selectively produces the first to fourth accumulative addition results produced by the first to fourth accumulative adders 8-0-0, 8-0-1, 8-0-2, and 8-0-3.

In the block diagram of FIG. 2, outputs of the first to sixteenth delay devices 1-0 to 1-15 are illustrated along with the process timing in a case where one channel having a sampling rate of (2×Fs) and two channels having a sampling rate of Fs are supplied according to the present exemplary embodiment.

The first multiplier 2-0 sequentially produces {C0×In0-3}, {C0×In1-0}, {C1×In0-4}, and {C0×In2-0} as the first multiplication result. The second multiplier 2-1 sequentially produces {C2×In0-5}, {C1×In1-1}, {C3×In0-6}, and {C1×In2-1} as the second multiplication result. The third multiplier 2-2 sequentially produces {C0×In0-4}, {C2×In1-2}, {C1×In0-5}, and {C2×In2-2} as the third multiplication result. The fourth multiplier 2-3 sequentially produces {C2×In0-6}, {C3×In1-3}, {C3×In0-7}, and {C3×In2-3} as the fourth multiplication result.

The first adder 3-0 sequentially produces {(C0×In0-3)+(C2×In0-5)}, {(C0×In1-0)+(C1×In1-1)}, {(C1×In0-4)+(C3×In0-6)}, and {(C0×In2-0)+(C1×In2-1)} as the first addition result. The second adder 3-1 sequentially produces {(C0×In0-4)+(C2×In0-6)}, {(C2×In1-2)+(C3×In1-3)}, {(C1×In0-5)+(C3×In0-7)}, and {(C2×In2-2)+(C3×In2-3)} as the second addition result. The third adder 3-2 sequentially produces {-}, {(c0×In1-0)+(C1×In1-1)+(C2×In1-2)+(C3×In1-3)}, {-}, and {(C0×In2-0)+(C1×In2-1)+(C2×In2-2)+(C3×In2-3)} as the third addition result.

The fifth accumulative adder 8-1-0 sequentially produces {(C0×In0-3)+(C2×In0-5)}, {-}, {(C0×In0-3)+(C2×In0-5)+(C1×In0-4)+(C3×In0-6)}, and {-} as the fifth accumulative addition result. The seventh accumulative adder 8-1-2 sequentially produces {(C0×In0-4)+(C2×In0-6)}, {-}, {(C0×In0-4)+(C2×In0-6)+(C1×In0-5)+(C3×In0-7)}, and {-} as the seventh accumulative addition result.

In this manner, for input data of multiple channels having different sampling rates, processing stages divided according to the sampling rate of each of the channels are performed in the respective processing stage regions on the delay circuit 1. Thus, a multichannel filtering process can be achieved with the maximum total sampling rate of (4×Fs).

Specifically, the configuration of the present exemplary embodiment can perform a multichannel filtering process of various sampling rate configurations such as {input data having a sampling rate of (4×Fs) have one channel}, {input data having a sampling rate of (2×Fs) have two channels}, {input data having a sampling rate of (2×Fs) have one channel+input data having a sampling rate of Fs have two channels}, and {input data having a sampling rate of Fs have four channels}. The configuration of {input data having a sampling rate of Fs have four channels} corresponds to the conventional multichannel filtering process.

This exemplary embodiment describes a case of four tap coefficients for the sake of brevity. However, the number of taps required in a sharp or narrow-band filter generally used in the telecommunication field is as large as several tens to a hundred and several tens. In this case, the number of components of the delay circuit 1, the multiplying circuit 2, and the adding circuit 3 is the same as that in the conventional multichannel filter circuit. Furthermore, the number of components of the stage-by-stage data delay circuit 4, the input selection part 5, the accumulative addition part 8, the output data format generation part 9, and the accumulative addition control part 10, which are newly added in the configuration according to the exemplary embodiment of the present invention, does not increase from the number illustrated in FIG. 2 of the present exemplary embodiment even if the number of taps increases. Only the number of components of the coefficient determination part 6 and the coefficient selection part 7, which are formed of selection circuits having a relatively small circuit complexity, increases in such a case.

Now the advantageous effects of a digital filter circuit according to the present exemplary embodiment will be described.

As described above, according to a digital filter circuit according to an exemplary embodiment of the present invention, a filtering process can be performed on a string of a plurality of input data having different sampling rates and a maximum total sampling rate of (n×Fs) with one circuit merely by adding a minimum circuit to a conventional digital filter circuit.

While the present invention has been particularly shown and described with reference to some exemplary embodiments thereof, the present invention is not limited to the aforementioned embodiments. It will be understood by those of ordinary skill in the art that various changes in forma and details may be made therein without departing from the sprit and scope of the present invention as defined by the claims.

For example, the aforementioned exemplary embodiments describe the case where n=4. Nevertheless, the present invention is not limited to such a case. Thus, the present invention can cope with cases where n>4, by increasing the number of the delay circuit 1, the coefficient determination part 6, and the accumulative addition part 8 between the drawing taps.

The exemplary embodiment of FIG. 2 has a configuration in which the delay circuit 1 operates at the same rate as the subsequent coefficient selection part 7, multiplying circuit 2, and adding circuit 3. The tap outputs of the delay circuit 1 may selectively be produced on each of the processing stage regions at a rate L times the operation rate of the delay circuit 1 so that the coefficient selection part 7, the multiplying circuit 2, and the adding circuit 3 operate at the L-fold rate. Then, in a new accumulative adder, a product-sum operation result corresponding to the output of the selected delay device may be accumulatively added at the aforementioned L-fold rate, so that the same filtering process as described in the aforementioned exemplary embodiment can be implemented. Additionally, the number of multipliers can be reduced by a factor of (1/L).

Furthermore, in the exemplary embodiment of FIG. 2, the filter outputs are produced by the output data format generation part 9 individually with each of the input sampling rates. Nevertheless, the present invention is not limited to such an example. The filter outputs may be regenerated into a time-division format that incorporates the filter outputs corresponding to input data for each of the sampling rates.

Moreover, the exemplary embodiment of FIG. 2 describes the configuration in which the sampling rates of multiple channels of the input data are set at values obtained by multiplying Fs by 2 raised to the power of a certain value (1, 2, or 4). Nevertheless, the present invention is not limited to such an example. For example, a filtering process for multiple channels with sampling rates up to the maximum total sampling rate (4×Fs) including a sampling rate of (3×Fs), i.e., a filtering process for channels having a sampling rate of multiplied Fs can be implemented by adding an input selection part 5 for ensuring three divided processing stage regions on the delay circuit 1.

Furthermore, with the configuration of the exemplary embodiment of FIG. 2, an individual coefficient can be set at the coefficient determination part 6 for the filtering process of each of the channels. Thus, for example, different filter properties, more specifically different tap coefficients, may be provided to input data having the same sampling rate. At that time, it is preferable to configure the delay circuit 1 so as to conform to a channel that requires a larger number of taps, fill zero into both ends of tap coefficients for a cannel that requires a smaller number of taps, and hold the tap coefficients in the coefficient determination part 6.

### INDUSTRIAL APPLICABILITY

The present invention is used for a digital filter circuit that processes a string of a plurality of input data having different sampling rates.

### DESCRIPTION OF REFERENCE NUMERALS AND SIGNS

1 . . . delay circuit
1-0 to 1-15 . . . delay device
2 . . . multiplying circuit
2-0 to 2-3 . . . multiplier
3 . . . adding circuit
3-0 to 3-2 . . . adder
4 . . . stage-by-stage data delay circuit
4-0 to 4-2 . . . stage-by-stage data delay device
5 . . . input selection part
5-0 to 5-2 . . . input selector
6 . . . coefficient determination part
6-0-0 to 6-3-3 . . . coefficient determining device
7 . . . coefficient selection part
7-0 to 7-3 . . . coefficient selector
8 . . . accumulative addition part
8-0-0 to 8-1-3 . . . accumulative adder
9 . . . output data format generation part
9-0 to 9-1 . . . output data selector
10 . . . accumulative addition control part
T0 to T3 . . . tap of delay circuit

This application is based upon and claims the benefit of priority from Japanese patent application No. 2011-110286, filed on May 17, 2011, the disclosure of which is incorporated herein in its entirety by reference.

1. A digital filter circuit with m tap coefficients configured to perform a multichannel filtering process for different sampling rates having a maximum total sampling rate of (n×Fs) where m≧2 and n≧2, the digital filter circuit comprising:
a delay circuit including (n×m) delay devices, the delay circuit being divided into first to mth groups of delay devices having first to mth taps, each groups of delay devices including n delay devices;
a processing stage division unit that selectively supplies first to (m−1)th input delayed signals obtained by delaying an input signal to the delay circuit by required sampling intervals and output signals of the second to mth taps to the first to (m−1)th groups of delay devices so that the (n×m) delay devices can be divided into k processing stage regions based upon the sampling rate of (k×Fs) where k≦n;
a tap coefficient supply unit that supplies first to mth tap coefficients selected for the first to mth taps, respectively;
a multiplying circuit including first to mth multipliers that multiply outputs of the first to mth taps and the first to mth selected tap coefficients to produce first to mth multiplication results, respectively;
an adding circuit including a plurality of adders that add up the first to mth multiplication results;
an accumulative addition part including a plurality of accumulative adders that accumulatively add the first to mth multiplication results and addition results of the plurality of adders to produce a plurality of accumulative addition results;
an output data format generation part that generates an output format of a filtering process result of each of processing stages from the plurality of accumulative addition results and outputs of the adding circuit; and
an accumulative addition control part that outputs a start signal of addition and a clear signal of the plurality of accumulative addition results to the plurality of accumulative adders.

2. The digital filter circuit as recited in claim 1, wherein the processing stage division unit includes:
a stage-by-state data delay circuit including first to (m−1)th stage-by-stage data delay devices that produce the first to (m−1)th input delayed signals obtained by delaying channels having a sampling rate of (k×Fs) whose filtering process has been divided into the k processing stage regions by the required sampling intervals corresponding to the processing stage regions where k≦n; and
an input selection part including first to (m−1)th input selectors that divide the (n×m) delay devices into the k processing stage regions based upon the sampling rate of (k×Fs) of a channel to be processed and that supply the first to (m−1)th input delayed signals and the outputs of the second to mth taps respectively to the first to (m−1)th groups of delay devices where k≦n.

3. The digital filter circuit as recited in claim 1, wherein the tap coefficient supply unit includes:
a coefficient determination part including first to mth groups of coefficient determining devices, each of which includes a plurality of coefficient determining devices, that determine tap coefficients for the first to mth taps that correspond to filtering processes of the processing stage regions based upon the multichannel sampling rate configuration; and
a coefficient selection part including first to mth coefficient selectors that selectively output a group of tap coefficients outputted from the first to mth groups of coefficient determining devices as the first to mth selected tap coefficients to the first to mth multipliers with a maximum total sampling rate of (n×Fs).

4. The digital filter circuit as recited in claim 1, wherein, when m is equal to 4, the adding circuit includes:
a first adder that adds up the first multiplication result and the second multiplication result to produce a first addition result;
a second adder that adds up the third multiplication result and the fourth multiplication result to produce a second addition result; and
a third adder for adding that adds up the first addition result and the second addition result to produce a third addition result as an output signal of the adding circuit.

5. The digital filter circuit as recited in claim 4, wherein the accumulative addition part includes:
first to fourth accumulative adders that accumulatively add the first to fourth multiplication results, respectively, to produce first to fourth accumulative addition results, respectively;
fifth and sixth accumulative adders that accumulatively add the first addition result to produce fifth and sixth accumulative addition results, respectively; and
seventh and eighth accumulative adders accumulatively add the second addition result to produce seventh and eighth accumulative addition results, respectively.

6. The digital filter circuit as recited in claim 5, wherein the output data format generation part includes:
a first output data selector that selectively produces the fifth to eighth accumulative addition results, and
a second output data selector for that selectively produces the first to fourth accumulative addition results.

7. The digital filter circuit as recited in claim 2, wherein the tap coefficient supply unit includes:
a coefficient determination part including first to mth groups of coefficient determining devices, each of which includes a plurality of coefficient determining devices, that determine tap coefficients for the first to mth taps that correspond to filtering processes of the processing stage regions based upon the multichannel sampling rate configuration; and
a coefficient selection part including first to mth coefficient selectors that selectively output a group of tap coefficients outputted from the first to mth groups of coefficient determining devices as the first to mth selected tap coefficients to the first to mth multipliers with a maximum total sampling rate of (n×Fs).
